(19) United States
(12) Patent Application Publication
(10) Pub. No.: US 2023/0117559 A1
(43) Pub. Date: Apr. 20, 2023

(54) SENSING MODULE

(71) Applicant: Coretronic MEMS Corporation, MIAOLI COUNTY (TW)

(72) Inventors: Mei-Ling Chen, MIAOLI COUNTY (TW); Wen-Pin Tsai, MIAOLI COUNTY (TW); Ming-Ching Wu, MIAOLI COUNTY (TW)

(73) Assignee: Coretronic MEMS Corporation, MIAOLI COUNTY (TW)

(21) Appl. No.: 17/960,147

(22) Filed: Oct. 5, 2022

(30) Foreign Application Priority Data
Oct. 15, 2021 (TW) 110212101

(51) Int. Cl. G01P 15/08; B81B 7/00; G01L 19/14; G01L 19/00

(52) U.S. Cl. CPC G01P 15/08; B81B 7/0032; G01L 19/147; G01L 19/0069; B81B 2201/02

(57) ABSTRACT

A sensing module including a circuit substrate, a sensing element, a packaging material and a blocking structure is provided. The sensing element, the packaging material and the blocking structure are disposed on the circuit substrate. The sensing element comprises a sensing portion. The outer side surface of the blocking structure is in direction contact with the packaging material to define a boundary of the packaging material. The sensing portion is disposed in a region encircled by the boundary of the packaging material, and the maximum thickness of the packaging material from a surface facing away from the circuit substrate to the circuit substrate is less than or equal to a distance from the second surface of the blocking structure to the circuit substrate.

### CROSS-REFERENCE TO RELATED APPLICATION

This application claims the priority benefit of Taiwan application serial no. 110212101, filed on Oct. 15, 2021. The entirety of the above-mentioned patent application is hereby incorporated by reference herein and made a part of this specification.

### BACKGROUND

### Technical Field

The invention relates to a sensing module.

### Description of Related Art

Micro-electro-mechanical system (MEMS) technology is a design based on a miniaturized electromechanical integrated structure. At present, the MEMS technology is commonly and mainly used in three fields, such as micro sensors, micro actuators, micro structures, and the like. The micro sensors may convert an external environment change (such as a force, a pressure, a sound, a speed, and the like.) into an electrical signal (such as a voltage, a current, or the like) to achieve an environmental sensing function, like force sensing, pressure sensing, sound sensing, acceleration sensing, etc. Since the micro sensors may be manufactured by using a semiconductor process technology and may be integrated with integrated circuits, the micro sensors have better competitiveness. Therefore, the MEMS sensors and sensing devices using the MEMS sensors are actually a development trend of micro-electro-mechanical systems.

Regarding MEMS force sensors, a sensing element thereof is used to sense a pressing force applied by an entity, and if the sensing element is exposed and directly subjected to the pressing force, the sensing element is easily worn out. Therefore, a technology for adding colloid to the sensing element to enhance a withstand strength of a sensing film has been developed. However, the sensing elements in the prior art are all connected to the circuit board by means of protruding terminals. When an applied force is too large, or the force is obliquely applied, there is a possibility that the protruding terminals or solder pads fall off from the circuit board. In other words, the maximum load-bearing limit of the sensing element is limited by a bonding strength of the protruding terminals or the solder pads. On the other hand, as a general packaging technology of the MEMS sensors requires development of molds for demolding a packaging material in the MEMS sensors, and based on the design requirement of a demolding angle, a lower limit of a product packaging size is limited, so that the manufacturing cost and the size of the product cannot be further reduced.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The invention is directed to a sensing module with a small size, low cost and good reliability.

Other objects and advantages of the invention may be further illustrated by the technical features broadly embodied and described as follows.

In order to achieve one or a portion of or all of the objects or other objects, an embodiment of the invention provides a sensing module including a circuit substrate, a sensing element, a packaging material and a blocking structure. The sensing element is disposed on the circuit substrate, and the sensing element has a sensing portion. The packaging material is disposed on the circuit substrate. The blocking structure is disposed on the circuit substrate. The blocking structure has a first surface, a second surface, and an outer side surface. The first surface faces the circuit substrate, the second surface faces away from the circuit substrate, the outer side surface is connected to the first surface and the second surface, and the outer side surface of the blocking structure is in direct contact with the packaging material to define a boundary of the packaging material, the sensing portion is disposed in a region encircled by the boundary of the packaging material, and the maximum thickness of the packaging material from a surface facing away from the circuit substrate to the circuit substrate is less than or equal to a distance from the second surface of the blocking structure to the circuit substrate.

Based on the above description, the embodiments of the invention have at least one of following advantages or effects. In the embodiments of the invention, with the configuration of the blocking structure, the packaging material may completely wrap and package the sensing element, the circuit element, and the sensing signal line outside the region encircled by the boundary of the blocking structure, so that the sensing module has good reliability, and configuration of demolding mold that defines the boundary of the packaging material is omitted, so as to further reduce the production cost and size of the product. In addition, with the configuration of the blocking structure, a volume and shape of the colloid may be appropriately controlled, and the colloid may be precisely positioned, which contributes to a mass production and improves consistency and yield of the product.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic structural diagram of a sensing module according to an embodiment of the invention.

FIG. 1B is a schematic top view of FIG. 1A.

FIG. 2 to FIG. 6 are structural schematic diagram of other sensing modules according to different embodiments of the invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention may be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

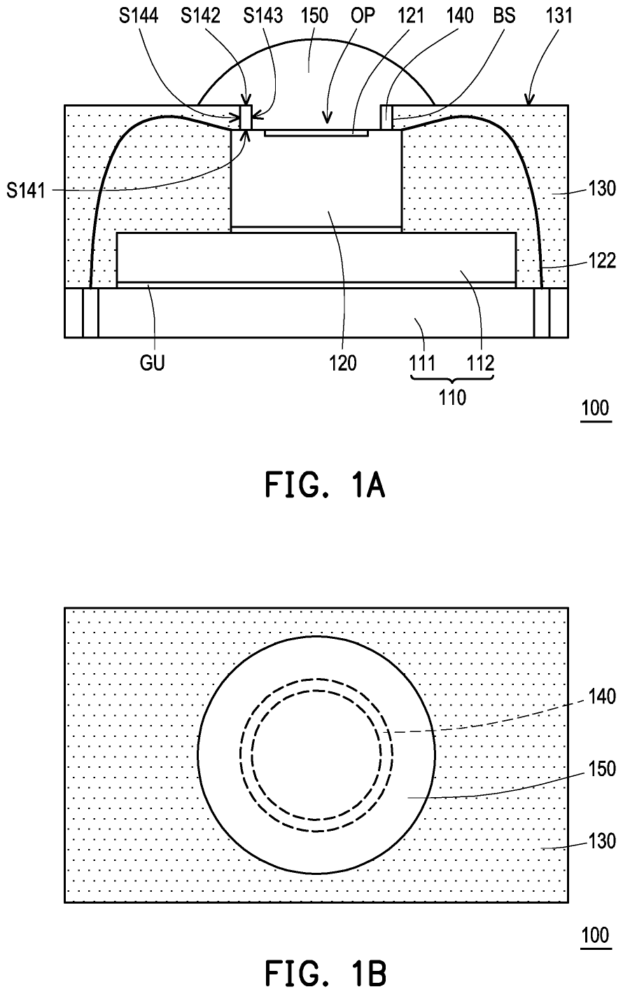

FIG. 1A is a schematic structural diagram of a sensing module according to an embodiment of the invention. FIG. 1B is a schematic top view of FIG. 1A, in order to clearly show the blocking structure in FIG. 1B, other related elements are omitted. Referring to FIG. 1A and FIG. 1B, the sensing module 100 of the embodiment includes a circuit substrate 110, a sensing element 120, a packaging material 130, and a blocking structure 140. The sensing element 120, the packaging material 130 and the blocking structure 140 are disposed on the circuit substrate 110. For example, in the embodiment, the sensing element 120 has a sensing portion 121 and a sensing signal line 122. In the embodiment, the sensing portion 121 of the sensing element 120 is electrically connected to the circuit substrate 110 through the sensing signal line 122 to transmit a sensing signal. However, the invention is not limited thereto. In other embodiments, the sensing signal line 122 may not be configured, but a circuit structure for electrically connection is configured on a contact surface of the circuit substrate 110 and the sensing element 120, which may also realize a function of transmitting the sensing signal.

Further, as shown in FIG. 1A, in the embodiment, the circuit substrate 110 includes a substrate 111 and a circuit element 112. The circuit element 112 is disposed on the substrate 111. For example, the circuit element 112 may be an application-specific integrated circuit. Further, in the embodiment, regarding the blocking structure 140, a polymer material such as photo resistor (PR), polyimide (PI), etc., may be used to first fabricate a structure with a height above the sensing element 120 in a wafer to form a preliminary structure by means of coating, exposing or developing. Then, the sensing element 120 with the blocking structure 140 is formed by means of cutting and separating the wafer. In this way, the blocking structure 140 with an appropriate thickness may be accurately positioned and fabricated on the sensing element 120 by using the existing semiconductor manufacturing process.

Thereafter, the sensing element 120 and the circuit element 112 may be adhered to the substrate 111 by using an adhesive layer GU. Then, the sensing signal line 122 and the substrate 111 are electrically connected by wire bonding. Thus, as shown in FIG. 1A, in the embodiment, the sensing element 120 is disposed on the circuit element 112, the circuit element 112 is disposed between the substrate 111 and the sensing element 120, and the blocking structure 140 is disposed on the sensing element 120, and as shown in FIG. 1B, the blocking structure 140 is a ring-shaped structure and has an opening OP that exposes the sensing portion 121 of the sensing element 120. In the embodiment, a shape encircled by the ring-shaped structure of the blocking structure 140 is not limited by the invention, which may be a circular ring, a rectangular ring, etc. To be specific, as shown in FIG. 1A, in the embodiment, the blocking structure 140 has a first surface S141, a second surface S142, an inner side surface S143, and an outer side surface S144, wherein the first surface S141 faces the circuit board 110, the second surface S142 faces away from the circuit board 110, and the inner side surface S143 and the outer side surface S144 respectively connect the first surface S141 and the second surface S142.

Then, the packaging material 130 is filled to form a main body of the sensing module 100 by using a molding method. To be specific, as shown in FIG. 1A and FIG. 1B, in the embodiment, the outer side surface S144 of the blocking structure 140 is in direct contact with the packaging material 130 to define a boundary BS of the packaging material 130, and the sensing portion 121 is disposed within a region encircled by the boundary BS of the packaging material 130. In detail, the blocking structure 140 is a structure used to prevent the packaging material 130 from overflowing into the sensing portion 121 during packaging. In other words, an area outside the region encircled by the boundary BS of the packaging material 130 is a coverage range of the packaging material 130, and the region encircled by the boundary BS is not covered by the packaging material 130. In other words, in the embodiment, an orthogonal projection of the blocking structure 140 on the circuit substrate 110 and an orthogonal projection of the packaging material 130 on the circuit substrate 110 are not overlapped.

In addition, since the blocking structure 140 is used to prevent the packaging material 130 from overflowing into the sensing portion 121 during packaging, a distance from an upper surface (i.e., the second surface S142) of the blocking structure 140 to the circuit substrate 110 may be greater than or equal to a thickness of the packaging material 130 on the circuit substrate 110. Namely, the maximum thickness of the packaging material 130 from a surface 131 facing away from the circuit substrate 110 to the circuit substrate 110 is less than or equal to the distance from the second surface S142 of the blocking structure 140 to the circuit substrate 110. As shown in FIG. 1A, in the embodiment, the maximum thickness of the packaging material 130 from the surface 131 to the circuit substrate 110 is the distance from the surface 131 of the packaging material 130 to the substrate 111 of the circuit substrate 110, and the distance from the second surface S142 of the blocking structure 140 to the circuit substrate 110 is the distance from the second surface S142 of the blocking structure 140 to the substrate 111 of the circuit substrate 110.

Therefore, as shown in FIG. 1A, the packaging material 130 completely wraps and packages the sensing element 120 and the circuit element 112 outside the region encircled by the boundary BS of the blocking structure 140. Namely, since the blocking structure 140 is disposed on the sensing element 120, the packaging material 130 wraps and packages a part of the sensing element 120 and a part of the circuit element 112 disposed outside the region encircled by the boundary BS of the blocking structure 140, the sensing element 120 may stably lean against the circuit substrate 110, and when the sensing element 120 is subjected to a force to perform sensing, the sensing element 120 will not fall off due to improper force applying. Moreover, in the embodiment, since the sensing signal line 122 is respectively connected to the part of the sensing element 120 and the part of the circuit substrate 110 disposed outside the region encircled by the boundary BS of the blocking structure 140, the sensing signal line 122 is also packaged in the packaging material 130, and a signal connection surface (i.e., an end point of the sensing signal line 122) and a force-receiving surface (i.e., the sensing portion 121) will not have possible mutual influence due to application of an external force. Therefore, when the sensing element 120 is subjected to a force to perform sensing, the sensing element 120 will not affect the sensing signal line 122 or a sensing result thereof, so that the sensing module 100 may have good reliability.

In addition, since the outer side surface S144 of the blocking structure 140 may be used to define the boundary BS of the packaging material 130, configuration of a demolding mold used to define the boundary BS of the packaging material 130 in the general packaging technology of MEMS sensor may be omitted, so as to reduce mold development cost and shorten a development schedule. Moreover, due to the characteristic that an included angle between the outer side surface S144 of the blocking structure 140 formed by means of coating, exposing, or developing and the surface of the sensing element 120 contacting the blocking structure 140 is close to a right angle, compared with the sensing module 100 that is generally formed by using a demolding mold for demolding, a configuration requirement of a bevel forming area for forming a demolding angle may be omitted, and the product size may be further reduced.

On the other hand, in the embodiment, the sensing module 100 further includes a colloid 150 disposed on the sensing portion 121 of the sensing element 120 for transmitting external force to the sensing portion 121, so as to further enhance a withstand strength of the sensing portion 121. Moreover, in the embodiment, the inner side surface S143 of the blocking structure 140 may also be used to define a volume and a position of the colloid 150. In this way, by arranging the blocking structure 140, the volume and shape of the colloid 150 may be appropriately controlled, and the colloid 150 may be precisely positioned, which helps mass production and improves the consistency and yield of the product.

In this way, by arranging the blocking structure 140, the packaging material 130 may completely wrap and package the sensing element 120, the circuit element 112, and the sensing signal line 122 outside the region encircled by the boundary BS of the blocking structure 140, so that the sensing module 100 may have good reliability, and configuration of the demolding mold that defines the boundary BS of the packaging material 130 may be omitted, which may further reduce the manufacturing cost and the size of the product. Moreover, by arranging the blocking structure 140, the volume and shape of the colloid 150 may be appropriately controlled, and the colloid 150 may be precisely positioned, which helps mass production and improves the consistency and yield of the product.

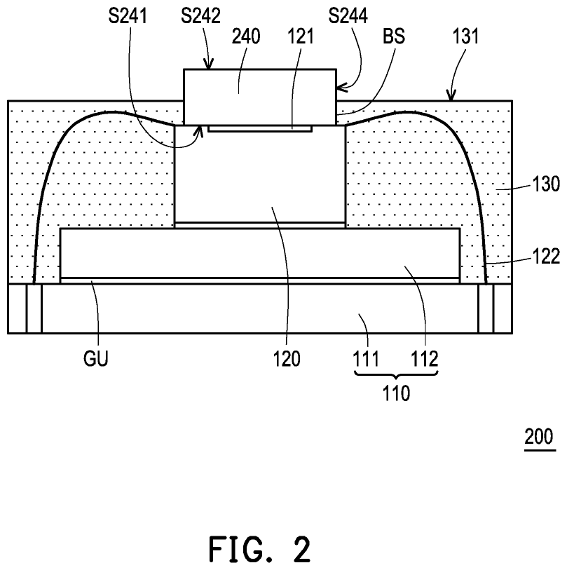

FIG. 2 is a structural schematic diagram of another sensing module according to an embodiment of the invention. Referring to FIG. 2, a sensing module 200 of the embodiment is similar to the sensing module 100 of FIG. 1A, and the differences there between are as follows. In the embodiment, a blocking structure 240 is a disc-shaped structure, the disk-shaped structure is stacked on the sensing portion 121 of the sensing element 120, and the blocking structure 240 protrudes relative to the packaging material 130, so that the external force may be transmitted to the sensing portion 121. In other words, the blocking structure 240 may replace the colloid 150 in FIG. 1A to form a structure that also has the functions of blocking the packaging material 130 from overflowing into the sensing portion 121 and transmitting the external force. Further, as shown in FIG. 2, in the embodiment, the maximum thickness of the packaging material 130 from the surface 131 facing away from the circuit substrate 110 to the circuit substrate 110 is smaller than a distance from a second surface S242 of the blocking structure 240 to the circuit substrate 110. In addition, the boundary BS of the packaging material 130 may be defined by the arrangement of a first surface S241, the second surface S242, and an outer side surface S244 of the blocking structure 240.

In this way, through the arrangement of the first surface S241, the second surface S242 and the outer side surface S244 of the blocking structure 240, the boundary BS of the packaging material 130 may be defined, and the packaging material 130 may completely wrap and package the sensing element 120, the circuit element 112, and the sensing signal line 122 outside the region encircled by the boundary BS of the blocking structure 240, so that the sensing module 200 may have good reliability, and configuration of the demolding mold that defines the boundary BS of the packaging material 130 may be omitted, which further reduces the production cost and size of the product, so that the sensing module 200 may have similar advantages as that of the aforementioned sensing module 100, and details thereof are not repeated.

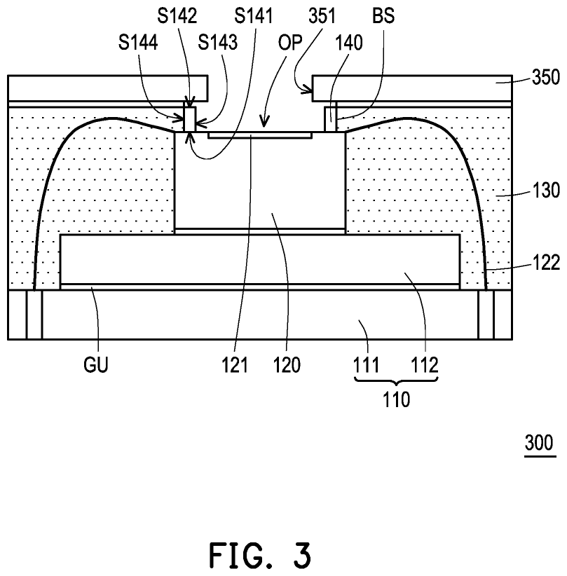

FIG. 3 is a structural schematic diagram of another sensing module according to an embodiment of the invention. Referring to FIG. 3, a sensing module 300 of the embodiment is similar to the sensing module 100 of FIG. 1A, and the differences there between are as follows. In the embodiment, the colloid 150 in FIG. 1A is omitted, and the sensing module 300 further includes a metal sheet 350, which is disposed on the sensing element 120, the packaging material 130, and the blocking structure 140, wherein the metal sheet 350 has a hole portion 351 that facilitates the opening OP of the blocking structure 140 communicating with the outside. In this way, through the configuration of the metal sheet 350, the sensing element 120 may be protected by the metal sheet 350, and through the configuration of the hole portion 351, the sensing element 120 may sense an external air pressure to realize a function of pressure sensing. Compared with a packaging process of a general pressure gauge, since the sensing module 300 of the embodiment may omit the demolding step of defining the boundary BS of the packaging material 130 and configuration of a mold, the packaging process is relatively simplified. Moreover, since the sensing module 300 has the configuration of the blocking structure 140 similar to that of the aforementioned sensing module 100, the sensing module 300 may also have similar advantages as that of the aforementioned sensing module 100, and details thereof are not repeated.

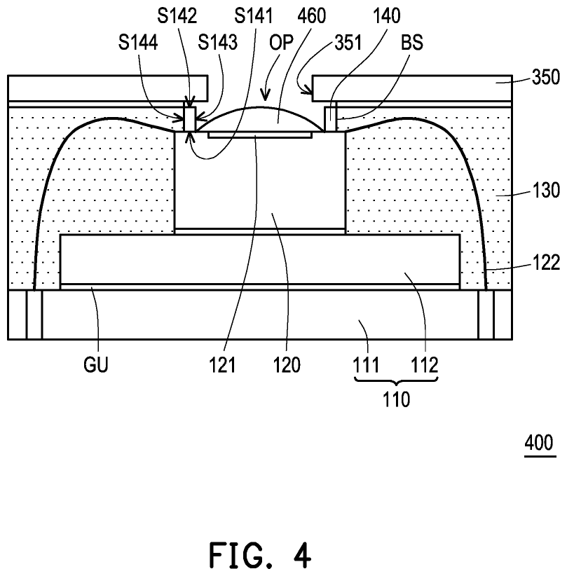

FIG. 4 is a structural schematic diagram of another sensing module according to an embodiment of the invention. Referring to FIG. 4, a sensing module 400 of the embodiment is similar to the sensing module 300 of FIG. 3, and differences there between are as follows. In the embodiment, the sensing portion 121 of the sensing element 120 is covered with a waterproof colloid 460, so that the sensing module 400 may be placed in a liquid environment. When the opening OP of the blocking structure 140 communicates with the outside filled with liquid, the sensing module 400 may be used to sense a liquid pressure. Moreover, since the sensing module 400 has the configuration of the blocking structure 140 similar to that of the aforementioned sensing module 300, the sensing module 400 may also have similar advantages as that of the aforementioned sensing module 300, and details thereof are not repeated.

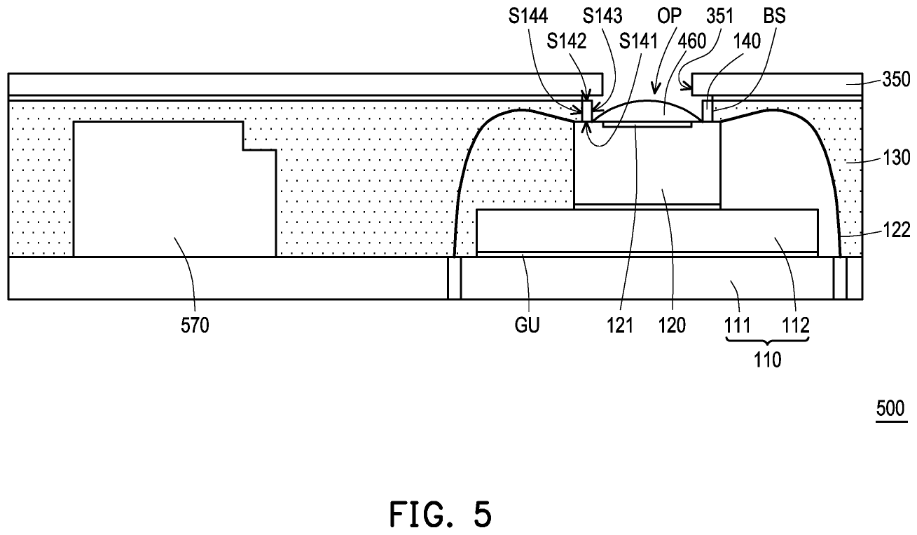

FIG. 5 is a structural schematic diagram of another sensing module according to an embodiment of the invention. Referring to FIG. 5, a sensing module 500 of the embodiment is similar to the sensing module 300 of FIG. 3, and differences there between are as follows. In the embodiment, the sensing module 500 further includes an acceleration sensing element 570, wherein the acceleration sensing element 570 is disposed on the circuit substrate 110 beside the blocking structure 140 and outside the region encircled by the boundary BS of the packaging material 130, and the packaging material 130 is also used for packaging the acceleration sensing element 570. In this way, the sensing module 500 may simultaneously have functions of sensing an acceleration velocity thereof and an environmental air pressure, so as to achieve a function of a tire pressure monitoring system (tpms). Moreover, since the sensing module 500 has the configuration of the blocking structure 140 similar to that of the aforementioned sensing module 300, the sensing module 500 may also have similar advantages as that the aforementioned sensing module 300, and details thereof are not repeated.

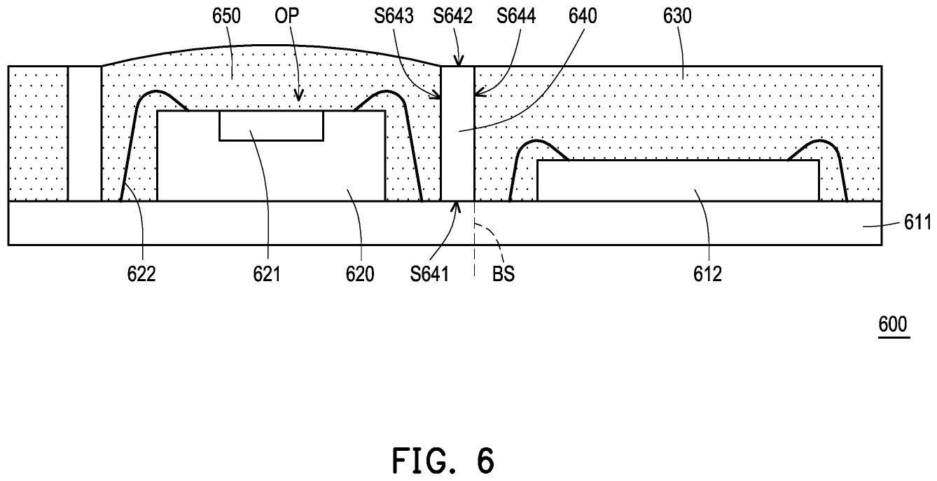

FIG. 6 is a structural schematic diagram of another sensing module according to an embodiment of the invention. Referring to FIG. 6, a sensing module 600 of the embodiment is similar to the sensing module 100 of FIG. 1A, and differences there between are as follows. In the embodiment, a sensing element 620, a blocking structure 640, and a circuit element 612 are all disposed on a surface of a substrate 611, i.e., the sensing element 620, the blocking structure 640, and the circuit element 612 are coplanar. The blocking structure 640 is a ring-shaped structure surrounding the sensing element 620 and has an opening OP that exposes the sensing element 620. A packaging material 630 is used to package the circuit element 612 outside the region encircled by the boundary BS of the packaging material 630, and a sensing signal line 622 is respectively connected to the sensing element 620 and a part of the substrate 611 within the region encircled by the boundary BS of the blocking structure 640, and in the embodiment, the sensing signal line 622 is packaged in a colloid 650. Since the sensing module 600 has the configuration of the blocking structure 640 similar to that of the aforementioned sensing module 100, and the boundary BS of the packaging material 630 and a volume and position of the colloid 650 may be defined through the arrangement of the first surface S641, the second surface S642, the inner side surface S643, and the outer side surface S644 of the blocking structure 640, the sensing module 600 may also have the similar advantages as that of the aforementioned sensing module 100, and details thereof are not repeated.

In addition, in other embodiments, the colloid 650 in FIG. 6 may also be omitted, and may be replaced by a metal sheet 350 to form a structure similar to that of the sensing modules 300 and 400 in FIG. 3 and FIG. 4, so as to implement the pressure sensing function, and achieve the similar advantages as that of the sensing modules 300 and 400, and details thereof are not repeated.

In addition, in the structure similar to the sensing modules 300 and 400 of FIG. 3 and FIG. 4, the acceleration sensing element 570 may also be added to the surface of the substrate 111 of any one of the sensing modules 300 and 400 to form a structure similar to the sensing module 500 of FIG. 5, so as to the function of the tire pressure monitoring system (tpms), and achieve the similar advantages as that of the aforementioned sensing module 500, and details thereof are not repeated.

In summary, the embodiments of the invention have at least one of following advantages or effects. In the embodiments of the invention, through the arrangement of the blocking structure, the packaging material may completely wrap and package the sensing element, the circuit element, and the sensing signal line outside the region encircled by the boundary of the blocking structure, so that the sensing module has good reliability, and configuration of demolding mold that defines the boundary of the packaging material may be omitted, so as to further reduce the production cost and size of the product. In addition, through the configuration of the blocking structure, a volume and shape of the colloid may be appropriately controlled, and the colloid may be precisely positioned, which helps a mass production and improves consistency and yield of the product.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the present disclosure is intended to be dedicated to the public regardless of whether the element or component is explicitly recited in the following claims.

What is claimed is:

1. A sensing module, comprising:
a circuit substrate;
a sensing element, disposed on the circuit substrate, and comprising a sensing portion;
a packaging material, disposed on the circuit substrate; and
a blocking structure, disposed on the circuit substrate, wherein the blocking structure comprises a first surface, a second surface, and an outer side surface, the first surface faces the circuit substrate, the second surface faces away from the circuit substrate, the outer side surface is connected to the first surface and the second surface, the outer side surface of the blocking structure is in direct contact with the packaging material to define a boundary of the packaging material, the sensing portion is disposed in a region encircled by the boundary of the packaging material, and a maximum thickness of the packaging material from a surface facing away from the circuit substrate to the circuit substrate is less than or equal to a distance from the second surface of the blocking structure to the circuit substrate.

2. The sensing module as claimed in claim 1, wherein an orthogonal projection of the blocking structure on the circuit substrate is not overlapped with an orthogonal projection of the packaging material on the circuit substrate.

3. The sensing module as claimed in claim 1, wherein the circuit substrate comprises:
a substrate; and
a circuit element, disposed on the substrate, wherein the maximum thickness of the packaging material from the surface to the circuit substrate is a distance from the surface of the packaging material to the substrate of the circuit substrate, and the distance from the second surface of the blocking structure to the circuit substrate is a distance from the second surface of the blocking structure to the substrate of the circuit substrate.

4. The sensing module as claimed in claim 3, wherein the sensing element is disposed on the circuit element, the circuit element is disposed between the substrate and the sensing element, and the packaging material is configured to package the sensing element and the circuit element outside the region encircled by the boundary.

5. The sensing module as claimed in claim 4, wherein the sensing element comprises a sensing signal line electrically connected to the circuit substrate to transmit a sensing signal, and the sensing signal line is packaged in the packaging material.

6. The sensing module as claimed in claim 4, wherein the blocking structure is disposed on the sensing element, and the blocking structure is a ring-shaped structure with an opening, wherein the opening exposes the sensing portion of the sensing element.

7. The sensing module as claimed in claim 6, further comprising:
a colloid, disposed on the sensing portion of the sensing element, and configured to transmit an external force to the sensing portion.

8. The sensing module as claimed in claim 6, further comprising:
a metal sheet, disposed on the packaging material and the blocking structure, wherein the metal sheet comprises a hole portion for the opening of the blocking structure to communicate with the outside.

9. The sensing module as claimed in claim 8, wherein the sensing portion is covered with a waterproof colloid.

10. The sensing module as claimed in claim 4, wherein the blocking structure is disposed on the sensing element, the blocking structure is a disc-shaped structure, the disc-shaped structure is stacked on the sensing portion of the sensing element, and the blocking structure protrudes out relative to the packaging material to transmit an external force to the sensing portion.

11. The sensing module as claimed in claim 4, wherein the sensing element, the blocking structure, and the circuit element are all disposed on a surface of the substrate, the blocking structure is a ring-shaped structure and comprises an opening that exposes the sensing element, and the packaging material is configured to package the circuit element.

12. The sensing module as claimed in claim 11, further comprising:
a colloid, disposed on the sensing portion of the sensing element, and configured to transmit an external force to the sensing portion.

13. The sensing module as claimed in claim 12, wherein the sensing element comprises a sensing signal line electrically connected to the circuit substrate to transmit a sensing signal, and the sensing signal line is packaged in the colloid.

14. The sensing module as claimed in claim 1, further comprising:
an acceleration sensing element, disposed on the circuit substrate beside the blocking structure and disposed outside the region encircled by the boundary of the packaging material, wherein the packaging material is further configured to package the acceleration sensing element.
